(19) United States
(12) Patent Application Publication
(10) Pub. No.: US 2025/0055254 A1
(43) Pub. Date: Feb. 13, 2025

(54) Semiconductor Laser

(71) Applicant: Nippon Telegraph and Telephone Corporation, Tokyo (JP)

(72) Inventors: Koji Takeda, Musashino-shi, Tokyo (JP); Shinji Matsuo, Musashino-shi, Tokyo (JP); Takuro Fujii, Musashino-shi, Tokyo (JP); Toru Segawa, Musashino-shi, Tokyo (JP); Yoshiho Maeda, Musashino-shi, Tokyo (JP)

(21) Appl. No.: 18/721,626

(22) PCT Filed: Dec. 20, 2021
(86) PCT No.: PCT/JP2021/047031

§ 371 Date: Jun. 18, 2024

(51) Int. Cl. H01S 5/10; H01S 5/06; H01S 5/12

(52) U.S. Cl. CPC H01S 5/101; H01S 5/0612; H01S 5/1209

(57) ABSTRACT

A semiconductor laser of the present invention includes: a waveguide structure including, in order, a first semiconductor layer, an active layer, and a second semiconductor layer; a p-type semiconductor layer disposed in contact with one side surface of the active layer; an n-type semiconductor layer disposed in contact with the other side surface of the active layer; a reflector optically coupled to one end of the active layer in a waveguide direction; a waveguide layer optically coupled to the other end of the active layer in the waveguide direction; a diffraction grating disposed on either one of a lower surface and an upper surface of the waveguide layer; and a refractive index control unit for changing a refractive index of the waveguide layer. Thus, the semiconductor laser of the present invention can provide a good high-temperature operation with a simple configuration.

### TECHNICAL FIELD

The present invention relates to a semiconductor laser having a diffraction grating and capable of operating at high temperatures.

### BACKGROUND ART

In recent years, in order to cope with the rapidly increasing transmission capacity of the Internet, it has become necessary to reduce the power consumption of optical devices, and in particular, semiconductor lasers capable of operating over a wide temperature range, from room temperature to high temperature, are needed.

In addition, as the module mounting density of optoelectronic devices increases, the device temperature increases, requiring semiconductor lasers capable of operating at high temperatures.

Conventionally, a semiconductor such as a DFB laser (Distributed feedback laser diode) can oscillate in a single mode by a structure comprising an active layer having a quantum well structure and a resonator structure such as a diffraction grating (NPLs 1 and 2). In order to obtain good laser characteristics, it is necessary that the gain wavelength of the active layer coincides with the resonance wavelength.

### CITATION LIST

### Non Patent Literature

[NPL 1] T. Fujii et al., “Heterogeneously Integrated Membrane Lasers on Si Substrate for Low Operating Energy Optical Links,” in IEEE Journal of Selected Topics in Quantum Electronics, vol. 24, No. 1, pp. 1-8, January-February 2018, Art No. 1500408, doi: 10.1109/JSTQE.2017.2778510.
[NPL 2] “Widely tunable laser with lattice filter on Si photonic platform,” Takuma Aihara, Tatsurou Hiraki, Takuro Fujii, Koji Takeda, Tai Tsuchizawa, Takaaki Kakitsuka, Hiroshi Fukuda, Shinji Matsuo, Compound Semiconductor Week 2021 (CSW 2021) TuA2-5 May 2021
[NPL 3] M. Chacinski, M. Isaksson and R. Schatz, “High-speed direct Modulation of widely tunable MG-Y laser,” in IEEE Photonics Technology Letters, vol. 17, No. 6, pp. 1157-1159, June 2005, doi: 10.1109/LPT.2005.846489.
[NPL 4] S. Paul et al., “10-Gb/s Direct Modulation of Widely Tunable 1550-nm MEMS VCSEL,” in IEEE Journal of Selected Topics in Quantum Electronics, vol. 21, No. 6, pp. 436-443, November-December 2015, Art No. 1700908, doi: 10.1109/JSTQE.2015.2418218.
[NPL 5] K. Hasebe, T. Sato, K. Takeda, T. Fujii, T. Kakitsuka and S. Matsuo, “High-Speed Modulation of Lateral p-i-n Diode Structure Electro-Absorption Modulator Integrated With DFB Laser,” in Journal of Lightwave Technology, vol. 33, No. 6, pp. 1235-1240, 15 Mar. 15, 2015, doi: 10.1109/JLT.2014.2383385.
[NPL 6] Gladyshev, A. G., Novikov, I. I., Karachinsky, L. Y. et al., “Optical properties of InGaAs/InGaAlAs quantum wells for the 1520-1580 nm spectral range,” Semiconductors 50, 1186-1190 (2016). https://doi.org/10.1134/S1063782616090098.

### SUMMARY OF INVENTION

### Technical Problem

In conventional DFB lasers, the temperature dependence of the gain wavelength and the temperature dependence of the refractive index are different, so changing the operating temperature causes a mismatch between the material gain and the oscillation wavelength, which degrades the characteristics.

Therefore, in the conventional DFB lasers, in order to operate with good characteristics at high temperatures, a configuration that operates at low temperatures with a temperature controller, a configuration that integrates a semiconductor modulator and a semiconductor optical amplifier, a configuration that uses materials that excel in high temperature operation for the active layer, and the like have been disclosed (NPLs 3 to 6).

However, since these configurations are complicated, there are problems such as complication of the manufacturing process and increase of the manufacturing cost.

### Solution to Problem

In order to solve the above problems, a semiconductor laser according to the present invention includes: a waveguide structure including, in order, a first semiconductor layer, an active layer, and a second semiconductor layer; a p-type semiconductor layer disposed in contact with one side surface of the active layer; an n-type semiconductor layer disposed in contact with the other side surface of the active layer; a reflector optically coupled to one end of the active layer in a waveguide direction; a waveguide layer optically coupled to the other end of the active layer in the waveguide direction; a diffraction grating disposed on either one of a lower surface and an upper surface of the waveguide layer; and a refractive index control unit for changing a refractive index of the waveguide layer.

### Advantageous Effects of Invention

According to the present invention, a semiconductor laser capable of achieving a good high-temperature operation with a simple configuration can be provided.

### BRIEF DESCRIPTION OF DRAWINGS

FIG. 1A is a top perspective view showing a configuration of a semiconductor laser according to a first embodiment of the present invention.

FIG. 1B is a cross-sectional view taken along IB-IB′, showing the configuration of the semiconductor laser according to the first embodiment of the present invention.

FIG. 1C is a cross-sectional view taken along IC-IC′, showing the configuration of the semiconductor laser according to the first embodiment of the present invention.

FIG. 2A is a diagram for explaining an operation of the semiconductor laser according to the first embodiment of the present invention.

FIG. 2B is a diagram for explaining an operation of the semiconductor laser according to the first embodiment of the present invention.

FIG. 2C is a diagram for explaining an operation of the semiconductor laser according to the first embodiment of the present invention.

FIG. 3 is a diagram for explaining an operation of the semiconductor laser according to the first embodiment of the present invention.

FIG. 4 is a top perspective view showing a configuration of a semiconductor laser according to a second embodiment of the present invention.

FIG. 5 is a top perspective view showing an example of the configuration of the semiconductor laser according to the second embodiment of the present invention.

FIG. 6 is a top perspective view showing an example of the configuration of the semiconductor laser according to the second embodiment of the present invention.

### DESCRIPTION OF EMBODIMENTS

### First Embodiment

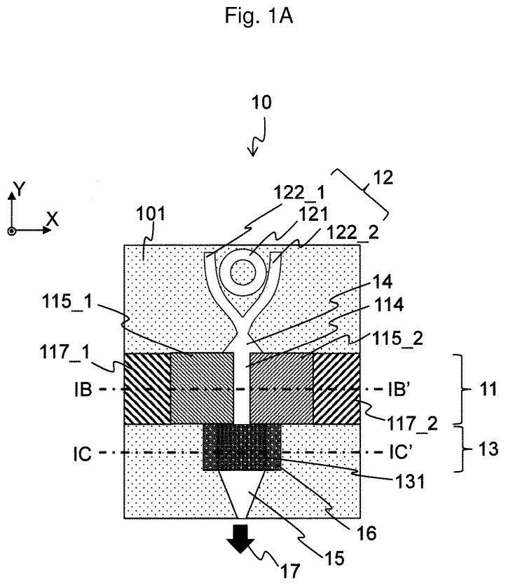

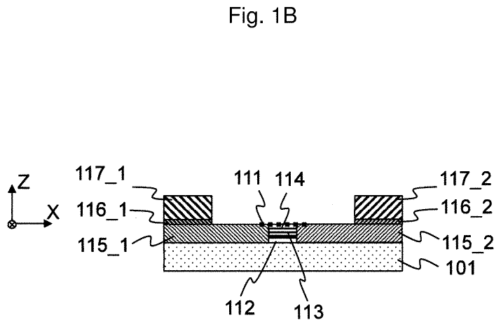

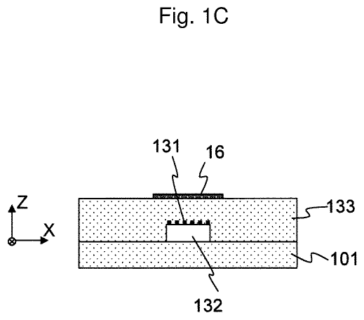

A first embodiment of the present invention will be described with reference to FIGS. 1A to 3.

### <Configuration of Semiconductor Laser>

As shown in FIG. 1A, a semiconductor laser according to the present embodiment has a gain region 11, a ring resonator 12, and a DBR (Distributed Bragg Reflector) region 13, on a SiO₂ 101.

Here, as the SiO₂ 101, a dielectric such as SiN or SiNO other than SiO₂ may be used. The SiO₂ 101 is formed on a substrate. Si is used for the substrate, and a semiconductor or a dielectric other than Si may be used.

As shown in FIG. 1B, the gain region 11 is formed into a waveguide structure by stacking a first semiconductor layer (InP) 112, a multi quantum well (MQW) 113 serving as an active layer, and a second semiconductor layer (InP) 114 on the SiO₂ 101. A p-type InP layer 115_1 is arranged in contact with one side surface of this waveguide structure in a width direction (X direction in the diagram), and a p-type electrode (for example, gold) 117_1 is provided on the p-type InP layer 115_1 via a p-type contact layer (for example, InGaAs) 116_1. An n-type InP layer 115_2 is arranged in contact with the other side surface, and an n-type electrode (for example, gold) 117_2 is provided on the n-type InP layer 115_2 via an n-type contact layer (for example, n-type InGaAs) 116_2.

Here, for example, the MOW active layer 113 is composed of an InGaAsP well layer and an InGaAsP barrier layer of a 1.55 μm wavelength band, and has a thickness of approximately 105 nm in six cycles. The thicknesses of the first semiconductor layer (InP) 112 and the second semiconductor layer (InP) 114 are 165 nm and 80 nm, respectively. The thickness of SiO₂ 101 is 2 μm, and the thicknesses of the p-type InP layer 115_1 and the n-type InP layer 115_2 are 350 nm.

Here, the MOW active layer 113 may be in a 1.31 μm wavelength band. InGaAs, InGaAlAs, GaInNAs, or the like may be used for the MOW instead of InGaAsP. Configurations such as the cycle and thickness of the MOW may employ other configurations.

The ring resonator 12 is optically coupled to the gain region 11 via a tapered optical coupler 14 in the waveguide direction, as shown in FIG. 1A.

In the ring resonator 12, two waveguides 122_1, 122_2 are optically coupled to a ring waveguide 121, and the two waveguides 122_1, 122_2 are multiplexed and demultiplexed by the tapered optical coupler 14.

The ring waveguide 121 and the tapered optical coupler 14 are made of InP.

As shown in FIG. 1A, the DBR region 13 is connected to the gain region 11 on the opposite side of the ring resonator 12 in the waveguide direction (Y direction in the diagram). Here, the DBR region 13 may be optically coupled to the gain region 11.

The DBR region 13 includes, as shown in FIG. 1C, an InP waveguide layer 132 and an SiO₂ cladding 133 covering the InP waveguide layer 132, on the SiO₂ 101, and has a heater 16 on an upper surface of the SiO₂ cladding 133.

In the DBR region 13, a DBR diffraction grating 131 is provided at a boundary between an upper surface of the InP waveguide layer 132 and the SiO₂ cladding 133. Alternatively, the DBR diffraction grating 131 may be provided at a boundary between a lower surface of the InP waveguide layer 132 and the SiO₂ 101.

Here, in the DBR diffraction grating 131, for example, a pitch (cycle) is approximately 200 nm to 300 nm, and a depth is approximately 10 nm to 50 nm, which are set by a desired light emission (oscillation) wavelength and a coupling coefficient. The coupling coefficient is preferably set so that the stopband width of the DBR is approximately equal to an FSR interval of the ring resonator described hereinbelow.

In the DBR region 13, the temperature of the InP waveguide layer 132 is changed by the heater 16, to change the refractive index. As a result, the coupling coefficient of the diffraction grating 131 of the InP waveguide layer 132 is changed, and the peak wavelength changes.

The heater 16 may be made of metal or resin. Although an example is shown in which the heater 16 is arranged on the upper surface of the SiO₂ cladding 133, the present embodiment is not limited thereto; the heater 16 may be embedded in the SiO₂ cladding 133 or SiO₂ 101, and the temperature of the InP waveguide layer 132 may be changed.

Here, for example, the lengths of the gain region 11 and the DBR region 13 are 75 μm and 10 μm, respectively, and the width of the active layer 113 of the gain region 11 and the width of the InP waveguide 122 of the DBR region 13 are 1.0 μm. Here, since the DBR region 13 is arranged on the light emission side, if too long, the reflectance becomes high, and the light cannot be efficiently emitted (taken out). Therefore, it is desirable to set the reflectance of the DBR region 13 to 5 to 50%.

The width of the ring waveguide 121 and the width of the waveguide coupled to the ring waveguide 121 are approximately 0.4 μm. The diameter of the ring waveguide 121 is approximately 5.0 to 10.0 μm.

An output waveguide 15 has a tapered shape that narrows in width toward an output end. The width of a tip (emission end) is approximately 0.1 μm. Therefore, for example, the laser beam is optically coupled to a waveguide having the waveguide disposed above or below the waveguide 15, and the laser beam is emitted.

Further, the output waveguide 15 may be taken as a simple linear waveguide, and the laser beam may be emitted through this waveguide.

### <Operation of Semiconductor Laser>

Operations of the semiconductor laser 10 according to the present embodiment will be described below.

In the semiconductor laser 10, light is produced by current injection in the gain region 11, emitted to the ring resonator 12 side, branched by the tapered optical coupler 14, propagates through each of the two waveguides 122_1, 122_2 in the ring resonator 12, and is coupled to the ring waveguide 121.

The light propagated through the waveguide 122_1 out of the two waveguides 122_1, 122_2 and coupled to the ring waveguide 121 circulates clockwise around the ring waveguide 121, is then coupled to the other waveguide 122_2, and returns to the tapered optical coupler 14. Further, the light propagated through the other waveguide 122_2 and coupled to the ring waveguide 121 circulates counterclockwise around the ring waveguide 121, is then coupled to the waveguide 122_1, and returns to the optical coupler 14.

The light that has returned from the ring waveguide 12 is multiplexed by the tapered optical coupler 14. In the ring resonator, only light with a wavelength that matches a resonance wavelength that the ring has returns to the gain region. There is not one resonance wavelength, but a plurality of resonance wavelengths corresponding to the number of circumferences of the ring exist.

On the other hand, the light emitted from the gain region 11 toward the DBR region 13 is selectively returned to the gain region in a mode matching a reflection spectrum of the DBR diffraction grating 131. The reflection spectrum has a shape having a finite stopband width which is centered on the Bragg wavelength of the diffraction grating and determined by the diffraction grating coupling coefficient and the diffraction grating length. Therefore, oscillation occurs at a wavelength selected by the DBR diffraction grating 131 out of resonance wavelengths of the ring resonator 12, and is emitted as a laser beam (arrow 17 in FIG. 1A).

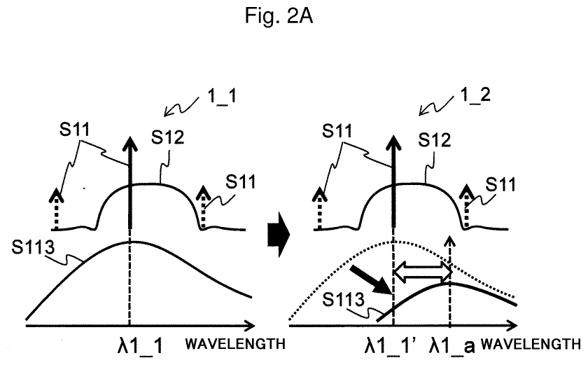

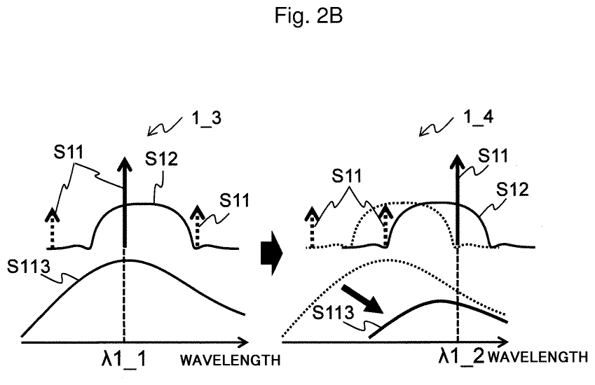

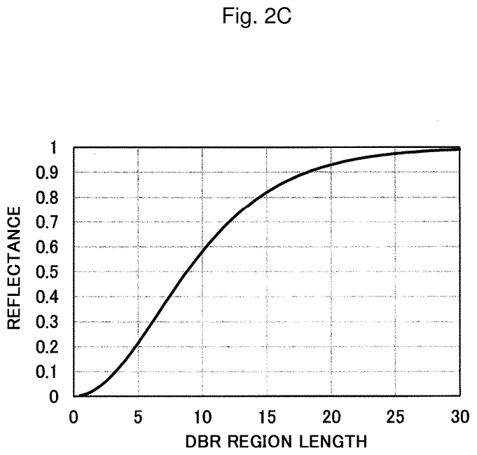

FIGS. 2A and 2B show a resonance wavelength S11 (solid arrow and dashed arrow in the diagram) of the ring resonator 12, a reflection spectrum S12 of the DBR diffraction grating 131, and a gain spectrum S113 of the MOW active layer, in the semiconductor laser in which the ring resonator 12 and the DBR diffraction grating 131 are integrated in the gain region.

FIG. 2A shows each wavelength/spectrum (1_1) at room temperature and each wavelength/spectrum (1_2) at high temperature in a case where the temperature is not controlled by the heater.

In this case, the DBR diffraction grating 131 selects and oscillates one of the resonance wavelengths of the ring resonator 12 (for example, λ1_1) (1_1 in the diagram).

At high temperature, the gain peak S113 of the MOW active layer shifts to the long wavelength side (wavelength λ1_a), and the intensity decreases. On the other hand, although the oscillation wavelength by the ring resonator 12 and the DBR diffraction grating 131 is also shifted to the long wavelength side, the shift amount of this wavelength (λ1_1′) is smaller than the shift amount of the gain peak. As a result, a deviation occurs between the gain peak (λ1_a) of the MOW active layer and the peak (λ1_1′) of the oscillation wavelength (1_2 in the diagram). Thus, the characteristics of this laser at a high temperature are deteriorated.

FIG. 2B shows each wavelength/spectrum (1_3) at room temperature and each wavelength/spectrum (1_4) at high temperature in a case where the temperature is controlled by the heater using the semiconductor laser 10 according to the present embodiment.

In the semiconductor laser 10, at room temperature, when the heater 16 is off, an oscillation wavelength by the ring resonator 12 and the DBR diffraction grating 131 and a wavelength of a gain peak of the MQW active layer 113 match at wavelength λ1_1 (1_3 in the diagram).

At high temperature, the heater 16 arranged in the vicinity of the InP waveguide layer 132 having the DBR diffraction grating 131 is turned on to raise the temperature (for example, approximately 100° C.), and the temperature of the InP waveguide layer 132 of the DBR diffraction grating 131 is increased. As a result, the refractive index of the InP waveguide layer 132 of the DBR diffraction grating 131 is increased, and the Bragg wavelength of the DBR diffraction grating 131 is shifted to the long wavelength side.

As a result, in the semiconductor laser 10, the Bragg wavelength of the DBR diffraction grating 131 match the resonance wavelength on the long wavelength side of the ring resonator 12, and oscillates at the emission wavelength (λ1_2) on the long wavelength side.

At high temperature, the gain peak of the MOW active layer 113 is also shifted to the long wavelength side as described above (1_4 in the diagram).

In this manner, in the semiconductor laser 10, at high temperature, since the resonance wavelength on the long wavelength side of the ring resonator 12 that matches the Bragg wavelength of the DBR diffraction grating 131 oscillates in unison with the gain peak of the MOW active layer 113, the reduction of the output at high temperature is suppressed, good and high-temperature operation characteristics are obtained.

According to the semiconductor laser according to the present embodiment, a decrease in output at high temperature is suppressed, and good high-temperature operation characteristics can be obtained.

In the semiconductor laser 10, a free-spectrum bandwidth (FSR) can be increased by reducing the circumferential length, that is, the diameter in the ring resonator 12. Further, when a semiconductor such as InP and silicon is used for the ring resonator 12 and a dielectric such as air, SiO₂, SiN, or SiON is used for the cladding, since the difference in refractive index between the core and the cladding is large and the light is strongly confined in the optical waveguide, the bend radius can be reduced and the ring resonator can be provided with a large FSR. Since the semiconductor laser 10 uses the ring resonator 12, the semiconductor laser 10 can operate in a wide band.

In the DBR region 13, one of the resonance wavelengths of the ring resonator 12 may be selected. If the stopband width of the DBR resonator 131 is too wide, there is a possibility that the DBR resonator 131 oscillates in two or more modes, and if too narrow, there is a possibility that the DBR resonator 131 does not oscillate in any mode, but by making the stopband width approximately equivalent to the FSR interval of the ring resonator, it becomes easier to select one mode in a stable manner. The reflectance of a DBR mirror may be determined in accordance with desired characteristics. FIG. 2C shows the results of calculation of the reflectance of the diffraction grating with a diffraction grating coupling coefficient κ=1000 cm⁻¹ with a stopband width of approximately 20 nm. The desired reflectance varies depending on the desired characteristics and may be approximately 5% to 60%, and the length of the DBR region at this time is 2.5 to 10.5 μm.

### <Effects of Semiconductor Laser>

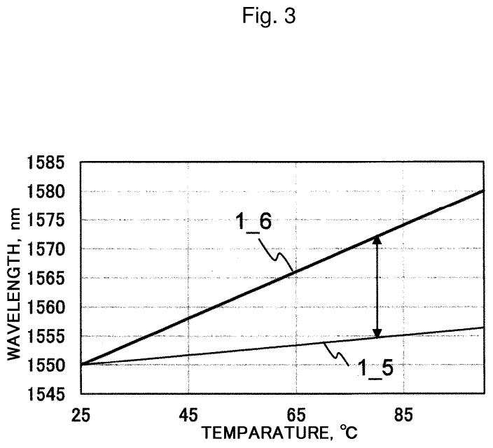

FIG. 3 shows a calculation result of temperature dependence between the oscillation peak wavelength and the gain peak wavelength in the semiconductor laser.

In the calculation, experimental data obtained by a semiconductor (DFB) laser was used for the temperature characteristics of the gain and the temperature dependence of the oscillation wavelength, which were set at 0.4 nm/K and 0.085 nm/K, respectively. The transmission refractive index was 2.7 for the 1.55-μm wavelength band and 2.9 for the 1.31-μm wavelength band. The active layer length was changed so that K·L=5.

As shown in FIG. 3, when one oscillation wavelength 1_5 in the semiconductor laser is made to match the gain peak wavelength 1_6 at room temperature and the temperature is increased, both the oscillation wavelength 1_5 and the gain peak wavelength 1_6 are shifted to the long wavelength side.

Here, the shift amount of the gain peak wavelength 1_6 is larger than the shift amount of the oscillation wavelength 1_5, and the difference therebetween is 18.9 nm at 80° C. (arrow in the diagram). At this time, since the full width at half maximum of the gain spectrum m of the normal MOW active layer 113 is approximately 40 nm, it is estimated that the gain is reduced to about half.

As described above, it is desirable to provide a structure capable of shifting the oscillation wavelength by approximately 20 nm, assuming an operation performed when the temperature changes between room temperature and high temperature (for example, approximately 80° C.) in the semiconductor laser. In the present invention, since the FSR interval can be freely set by changing the diameter of the ring, wavelength switching at a desired wavelength interval can be performed.

For example, in a configuration in which laser oscillation is performed using a DFB laser, when a similar wavelength switching function is realized, two oscillation wavelengths can be obtained by using a uniform diffraction grating having a wide stopband width of the DFB. The difference between the wavelength for oscillation at room temperature and the wavelength for oscillation at high temperature is determined by the stopband width of the DFB diffraction grating. Here, the DFB stopband width substantially depends on the coupling coefficient of the diffraction grating.

Therefore, in order to widen the operating wavelength range of the laser, that is, the stopband width, it is necessary to increase the coupling coefficient of the diffraction grating.

However, when the coupling coefficient of the diffraction grating is increased, the product KL with the active layer length is increased, and it is difficult to stably oscillate in a single mode due to the influence of spatial hole burning or the like. This problem is remarkable in a laser having a long active layer exceeding, for example, 300 μm.

On the other hand, in the semiconductor laser according to the present embodiment, since the resonance wavelength interval is determined by the FSR interval of the ring resonator, the operating wavelength range of the laser can be widened regardless of the coupling coefficient of the diffraction grating. Therefore, even in a laser having a long active layer, it is possible to easily and stably oscillate in a single mode and in a wide band.

### Second Embodiment

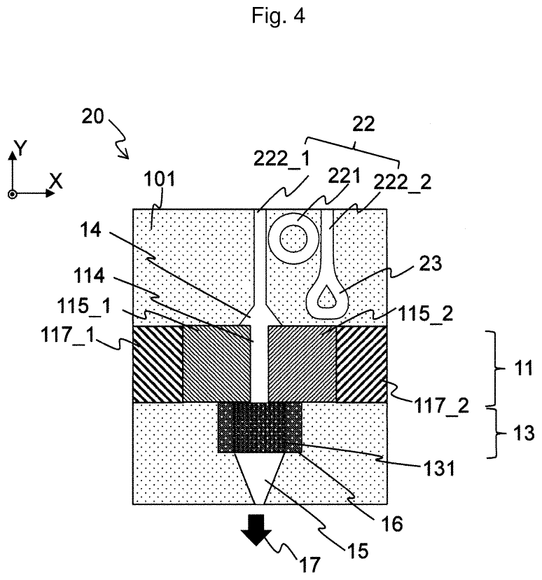

A semiconductor laser according to a second embodiment of the present invention will be described hereinafter with reference to FIG. 4.

### <Configuration of Semiconductor Laser>

As shown in FIG. 4, a semiconductor laser 20 according to the present embodiment has a gain region 11, a ring resonator 22, a DBR (Distributed Bragg Reflector) region 13, and a loop mirror 23, on a SiO₂ 101.

In the ring resonator 22, two waveguides 222_1, 222_2 are optically coupled to a ring waveguide 221, and of the two waveguides 222_1, 222_2, the waveguide 222_1 is optically coupled to the gain region 11 via a taper 14. The other waveguide 222_2 has a loop mirror 23 at one end. The ring waveguide 221, the taper 14 and the loop mirror 23 are made of InP. The other configurations are the same as those of the first embodiment.

In the semiconductor laser 20, light is produced by current injection in the gain region 11, and output to the ring resonator 22 side via the taper 14. In the ring resonator 22, one waveguide 222_1 propagates and is coupled to the ring waveguide 221.

The light coupled to the ring waveguide 221 circulates clockwise around the ring waveguide 221. Part of the circulated light is coupled to the other waveguide 222_2, propagates through the waveguide 222_2, and is reflected by the loop mirror 23. The reflected light is again coupled to the ring waveguide 221, and circulates counterclockwise around the ring waveguide 221. Part of the circulated light is coupled to one waveguide 222_1, propagates through the waveguide 222_1, and returns to the gain region 11 through the taper 14.

On the other hand, as in the first embodiment, the light emitted from the gain region toward the DBR region 13 selectively returns to the gain region with a mode that matches the reflection spectrum of the DBR grating 131. Therefore, out of resonance wavelengths of the ring resonator 22, oscillation occurs at a wavelength selected by the DBR diffraction grating 131, and the oscillation is emitted as a laser beam.

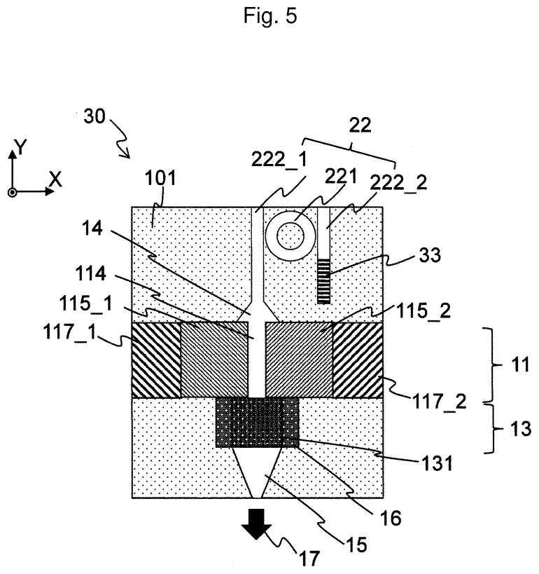

The present embodiment has described an example in which the loop mirror 23 is used, but in place of the loop mirror 23, as shown in FIG. 5, the DBR diffraction grating 33 may be formed at an end of the other waveguide 222_2, and a configuration may be possible in which the oscillation light emitted from the ring resonator 22 is reflected (light reflection part).

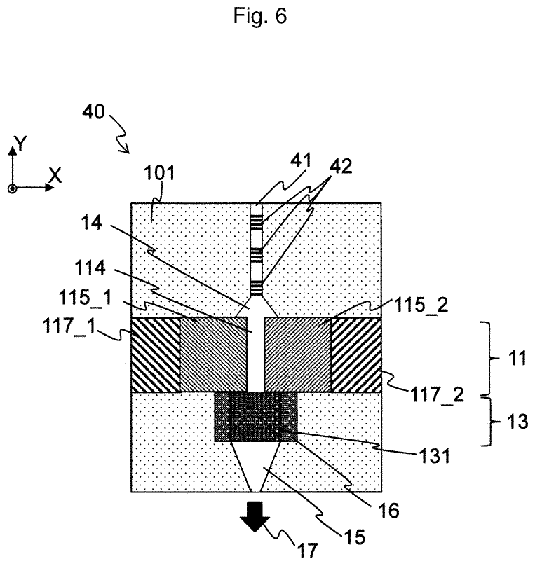

The embodiments of the present invention have described an example in which the ring resonator 22 is used, but the present invention is not limited thereto; a sampled grating 42 may be formed in a waveguide 41 that is optically coupled to the gain region 11, as shown in FIG. 6. Similarly to the ring resonator, the sampled grating can also generate oscillation light by reflecting the light emitted from the gain region 11 in multi-mode, so that the same effects as those of the embodiments of the present invention can be achieved. Thus, it is sufficient that the sampled grating be optically coupled to the gain region 11 to reflect the light emitted from the gain region 11 in multi-mode to generate oscillation light, and function as a reflector.

Although the embodiments of the present invention have described an example in which the wavelength of the DBR region is shifted by the heater, the present invention is not limited thereto. An electrode connected to a power source may be arranged in the waveguide layer of the DBR region, and a reverse bias may be applied to extract a carrier, thereby changing the refractive index to shift the wavelength of the DBR region. In this manner, a configuration for changing the refractive index of the DBR region (hereinafter referred to as a “refractive index control unit”) may be provided.

If the refractive index control unit is a heater, the heater is turned on to increase the temperature of the DBR region, thereby increasing the refractive index. Further, the refractive index can be increased by turning on the refractive index control unit and applying a reverse bias to the DBR region to extract a carrier. In this manner, the refractive index of the DBR region can be increased in a state where the refractive index control unit is on, and the wavelength of the DBR region can be shifted to the long wavelength side.

In the embodiments of the present invention, a state in which the emission wavelength of the ring resonator matches the Bragg wavelength of the DBR diffraction grating refers to, for example, as shown in FIG. 2A, a state in which the emission peak in the emission spectrum of the ring resonator and a broad peak in the reflection spectrum of the DBR diffraction grating overlap each other. At this time, since only one light emission (for example, the short wavelength side) of the ring resonator is subjected to feedback by the DBR diffraction grating, the light emission on the short wavelength side can be taken out in the ring resonator.

The embodiments of the present invention have described an example in which the ring resonator and the DBR region are optically coupled to the gain region, but in this case, the waveguides in the ring resonator and the DBR region may be optically coupled to the active layer of the gain region.

The embodiments of the present invention have described an example of a configuration of a semiconductor laser with wavelength bands of 1.55 μm and 1.31 μm, but other wavelength bands may be used. In addition, an example of a configuration using an InP-based compound semiconductor has been described as a layer configuration of a semiconductor laser such as an active layer, a waveguide layer, and p-type and n-type semiconductor layers, but other InP-based compound semiconductors may be used, other semiconductors such as GaAs-based or Si-based semiconductors may be used, and a material capable of constituting a semiconductor laser may be used.

Although the embodiments of the present invention have described examples of structures, dimensions, materials, and the like of each component in the configurations of the semiconductor laser and the manufacturing method thereof, but the present invention is not limited thereto. Any modifications can be made as long as the modifications bring about the functions of a semiconductor laser and achieves the effects.

### INDUSTRIAL APPLICABILITY

The present invention can be applied to light-emitting devices in Internet communication systems, computer systems, and the like.

### REFERENCE SIGNS LIST

10 Semiconductor laser
112 First semiconductor layer
113 Active layer
114 Second semiconductor layer
115_1 p-type semiconductor layer
115_2 n-type semiconductor layer
12 Reflector (ring resonator)
131 Diffraction grating
132 Waveguide layer
16 Refractive index control unit

1. A semiconductor laser, comprising:
a waveguide structure including, in order, a first semiconductor layer, an active layer, and a second semiconductor layer;
a p-type semiconductor layer disposed in contact with one side surface of the active layer;
an n-type semiconductor layer disposed in contact with the other side surface of the active layer;
a reflector optically coupled to one end of the active layer in a waveguide direction;
a waveguide layer optically coupled to the other end of the active layer in the waveguide direction;
a diffraction grating disposed on either one of a lower surface and an upper surface of the waveguide layer; and
a refractive index control unit for changing a refractive index of the waveguide layer.

2. The semiconductor laser according to claim 1, wherein the reflector generates oscillation light with a plurality of modes,
in a state where the refractive index control unit is off, the oscillation light of a predetermined wavelength among the oscillation light with the plurality of modes is selected by the diffraction grating and oscillated, and
in a state where the refractive index control unit is on, the oscillation light on a longer wavelength side than a predetermined wavelength among the oscillation light with the plurality of modes is selected by the diffraction grating and oscillated.

3. The semiconductor laser according to claim 1, wherein the reflector is a ring resonator.

4. The semiconductor laser according to claim 3, further comprising a loop mirror optically coupled to the ring resonator.

5. The semiconductor laser according to claim 3, further comprising a waveguide optically coupled to the ring resonator and having a diffraction grating at one end.

6. The semiconductor laser according to claim 1, wherein the reflector is a waveguide having a sampled grating.

7. The semiconductor laser according to claim 1, wherein the refractive index control unit is a heater.

8. The semiconductor laser according to claim 1, wherein the refractive index control unit is an electrode connected to a power source and arranged in the waveguide layer, the electrode being applied with a bias to change a carrier density of the waveguide layer.

9. The semiconductor laser according to claim 2, wherein the reflector is a ring resonator.

10. The semiconductor laser according to claim 2, wherein the reflector is a waveguide having a sampled grating.

11. The semiconductor laser according to claim 2, wherein the refractive index control unit is a heater.

12. The semiconductor laser according to claim 3, wherein the refractive index control unit is a heater.

13. The semiconductor laser according to claim 4, wherein the refractive index control unit is a heater.

14. The semiconductor laser according to claim 5, wherein the refractive index control unit is a heater.

15. The semiconductor laser according to claim 6, wherein the refractive index control unit is a heater.

16. The semiconductor laser according to claim 2, wherein the refractive index control unit is an electrode connected to a power source and arranged in the waveguide layer, the electrode being applied with a bias to change a carrier density of the waveguide layer.

17. The semiconductor laser according to claim 3, wherein the refractive index control unit is an electrode connected to a power source and arranged in the waveguide layer, the electrode being applied with a bias to change a carrier density of the waveguide layer.

18. The semiconductor laser according to claim 4, wherein the refractive index control unit is an electrode connected to a power source and arranged in the waveguide layer, the electrode being applied with a bias to change a carrier density of the waveguide layer.

19. The semiconductor laser according to claim 5, wherein the refractive index control unit is an electrode connected to a power source and arranged in the waveguide layer, the electrode being applied with a bias to change a carrier density of the waveguide layer.

20. The semiconductor laser according to claim 6, wherein the refractive index control unit is an electrode connected to a power source and arranged in the waveguide layer, the electrode being applied with a bias to change a carrier density of the waveguide layer.
